(19) United States
(12) Patent Application Publication
(10) Pub. No.: US 2026/0223502 A1
(43) Pub. Date: Jul. 30, 2026

(54) MAGNET ASSEMBLY APPARATUS OF SEMICONDUCTOR LIGHT-EMITTING DEVICE FOR PIXELS, AND SELF-ASSEMBLY APPARATUS OF SEMICONDUCTOR LIGHT-EMITTING DEVICE FOR DISPLAY PIXELS, COMPRISING SAME

(71) Applicant: LG ELECTRONICS INC., Seoul (KR)

(72) Inventor: Yangwoo BYUN, Seoul (KR)

(73) Assignee: LG ELECTRONICS INC., Seoul (KR)

(21) Appl. No.: 19/145,172

(22) PCT Filed: Jan. 2, 2023
(86) PCT No.: PCT/KR2023/000019

§ 371 Date: Jul. 1, 2025

(51) Int. Cl. H10H 29/03; H10H 29/01

(52) U.S. Cl. CPC H10H 29/03; H10H 29/012

(57) ABSTRACT

The embodiment relates to a magnet assembly device for a pixel semiconductor light emitting device and a self-assembly apparatus for a display pixel semiconductor light emitting device including the same. According to an embodiment, the magnet assembly device for the semiconductor light emitting device for pixels may be disposed on a predetermined assembly substrate and may apply a magnetic force to the semiconductor light emitting device. The magnet assembly device may include a magnet rotation unit and a magnet unit mounted on the magnet rotation unit. The magnet rotation unit may include a magnet driving unit and a magnet gear unit. The magnet unit may rotate around a rotation axis, including a N-pole magnet region and a S-pole magnet region. In the magnet unit, the N-pole magnet region and the S-pole magnet region may be disposed in a direction parallel to a surface of the assembly substrate.

### TECHNICAL FIELD

The embodiment relates to a self-assembly apparatus for semiconductor light emitting devices for display pixels. Specifically, the embodiment relates to a magnet assembly device for semiconductor light emitting devices for pixels and a self-assembly apparatus for semiconductor light emitting devices for display pixels including the same.

### Background Art

Large-area displays include liquid crystal displays (LCDs), OLED displays, and micro-LED displays.

A micro-LED display is a display that uses micro-LEDs, which are semiconductor light emitting devices with a diameter or cross-sectional area of 100 μm or less, as display devices.

Since a micro-LED display uses micro-LEDs, which are semiconductor light emitting devices, as display devices, the micro-LED display has excellent performance in many characteristics such as contrast ratio, response speed, color reproducibility, viewing angle, brightness, resolution, lifespan, luminous efficiency, and luminance.

In particular, micro-LED displays have the advantage of being able to freely adjust the size and resolution by separating and combining the screen in a modular manner, and the advantage of being able to implement a flexible display.

However, since large micro-LED displays require millions of micro-LEDs, there is a technical problem that makes it difficult to quickly and accurately transfer micro-LEDs to the display panel.

Transferring technologies that are being developed recently include the pick and place process, the laser lift-off method, or the self-assembly method.

Among these, the self-assembly method is a method in which semiconductor light emitting devices find their own assembly positions in a fluid, and is advantageous for implementing large-screen display devices.

Recently, a micro-LED structure suitable for self-assembly has been proposed in U.S. Pat. No. 9,825,202, etc., but research on technology for manufacturing displays through self-assembly of micro-LEDs is still insufficient.

In particular, in the case of rapidly transferring millions or more semiconductor light emitting devices to a large display in the prior art, the transfer speed may be improved, but there is a technical problem that the transfer error rate may increase, which lowers the transfer yield.

In the internal technology, a self-assembly process using the magnetic force of a magnet and dielectrophoresis (DEP) is being studied.

The self-assembly process of the internal technology is carried out in the order of the assembly substrate surface treatment step, the assembly substrate loading step, the semiconductor light emitting device chip supply step, the assembly and chip recovery step, the inspection, drying, and substrate separation steps.

The assembly substrate loading step is a step of loading the assembly substrate onto the substrate chuck, and the assembly substrate loaded onto the substrate chuck is transferred to the assembly position of the assembly chamber. Thereafter, the magnetic field forming unit approaches the assembly substrate through vertical and horizontal movements.

In this state, the semiconductor light emitting device chip supply step is carried out. Specifically, a step of dispersing semiconductor light emitting devices on the assembly surface of the assembly substrate is performed. When the semiconductor light emitting devices are dispersed near the assembly surface while the magnetic field forming unit is sufficiently close to the assembly substrate, the semiconductor light emitting devices are attached to the assembly surface by the magnetic field forming unit.

For example, according to an internal technology, a cluster of semiconductor light emitting device chips containing magnetic materials may be moved by a large number of rotating magnetic rods, and the semiconductor light emitting device chips may be sequentially assembled into the assembly pockets of the assembly substrate in a subsequent process.

For example, self-assembly is performed using DEP force, and a step of recovering the semiconductor light emitting devices is performed. Finally, after the self-assembly is completed, the assembly substrate may be inspected, dried, and the substrate may be separated from the substrate chuck.

Meanwhile, the semiconductor light emitting device chips being supplied uniformly to the assembly holes of the assembly substrate has a significant effect on the assembly accuracy and assembly speed.

First, in the internal technology, the chip tray is placed in the assembly chamber, semiconductor light emitting device chips are supplied to the chip tray, and then the semiconductor light emitting devices are uniformly supplied to the assembly substrate using the chip tray to improve the assembly efficiency.

However, according to the internal technology, after the semiconductor light emitting devices are supplied to the chip tray, the semiconductor light emitting devices are self-assembled on the assembly substrate using magnetic force and DEP force, and it is difficult to control the direction of the semiconductor light emitting device chips so that the semiconductor light emitting device chips may not be properly assembled into the assembly holes of the assembly substrate. Accordingly, the problem of a decrease in the correct assembly rate is being studied.

For example, in the internal technology, the magnetic force of the magnet was used to move the semiconductor light emitting devices to a vicinity of the assembly holes of the assembly substrate, and it was not studied whether the arrangement direction of the semiconductor light emitting devices located near the assembly holes by the magnetic force was suitable for assembling into the assembly holes.

In addition, in the self-assembly of semiconductor light emitting devices for display pixels of internal technology, research was conducted to lower the assembly speed in order to increase the correct assembly rate, but a contradictory situation occurred in which multiple LED chips were assembled into one assembly hole due to the low assembly speed, resulting in incorrect assembly and an increase in residual LED chips.

### DISCLOSURE

### Technical Problem

One of the technical objects of the embodiment is to solve the problem in which the correct assembly rate is reduced because the direction of the semiconductor light emitting device chip may not be controlled so that the correct assembly may not be performed in the assembly hole of the assembly substrate in the self-assembly of semiconductor light emitting devices for display pixels.

The technical object of the embodiment is not limited to what is described in this item, and includes what may be understood throughout the entire specification.

### Technical Solution

The magnet assembly device for the semiconductor light emitting device for pixels according to the embodiment may be is disposed on a predetermined assembly substrate and may apply a magnetic force to the semiconductor light emitting device. The magnet assembly device may include a magnet rotation unit and a magnet unit mounted on the magnet rotation unit.

The magnet rotation part may include a magnet driving part and a magnet gear part.

The magnet unit may rotate around a rotation axis including a N-pole magnet region and a S-pole magnet region.

In the magnet unit, the N-pole magnet region and the S-pole magnet region may be disposed in a direction parallel to the surface of the assembly substrate.

A center of the magnet unit may be disposed eccentrically at a position off a center of the magnet gear part.

The magnet unit may rotate around a rotation axis (Rz) of the magnet driving part or an axis parallel thereto, and the rotation axis may be disposed at an outer region of a boundary between the N-pole magnet region and the S-pole magnet region of the magnet unit.

The magnet unit may further include a metal part including a ferromagnetic material on one or both sides of the N-pole magnet region or the S-pole magnet region.

The magnet unit may rotate around a rotation axis (Rz) of the magnet driving unit or an axis parallel thereto, and the rotation axis may be disposed at an outer region of the N-pole magnet region or the outer region of the S-pole magnet region.

In addition, the magnet assembly device for the semiconductor light emitting device for pixels according to the embodiment may include a magnet rotation unit and a magnet unit mounted on the magnet rotation unit, and the magnet rotation unit may include a magnet driving unit and a magnet gear unit.

A central axis of the magnet unit may rotate in a tilted state at a predetermined angle with respect to the rotation axis of the magnet driving unit.

A first rotation radius of an upper side of the magnet unit may be different from a second rotation radius of a lower side of the magnet unit.

The first rotation radius of the upper side of the magnet unit may be less than the second rotation radius of the lower side of the magnet unit.

In the magnet unit, the N-pole magnet region and the S-pole magnet region may be disposed in a direction parallel to the surface of the assembly substrate.

The lower surface of the magnet unit may be inclined with the surface of the assembly substrate.

A vertical cross-section of the magnet unit may include a parallelogram shape.

The upper surface of the magnet unit may be parallel to the surface of the magnet gear part.

The lower surface of the magnet unit may be parallel to the surface of the assembly substrate.

A center of the magnet unit may be eccentrically disposed at a position off the center of the magnet gear part.

The magnet unit may further include a metal part including a ferromagnetic material on one or both sides of the N-pole magnet region or the S-pole magnet region.

In addition, a self-assembly apparatus of the semiconductor light emitting device for display pixels according to the embodiment may include a chamber that accommodates a predetermined fluid and a plurality of semiconductor light emitting devices, an assembly substrate disposed on the chamber, and a magnet assembly device disposed on the assembly substrate. The magnet assembly device may include the magnet assembly device of any one of the semiconductor light emitting devices for pixels.

### Advantageous Effects

According to the magnet assembly device of the semiconductor light emitting device for pixels according to the embodiment and the self-assembly apparatus of the semiconductor light emitting device for display pixels including the same, in the self-assembly of the semiconductor light emitting device for display pixels, there is a technical effect of controlling the distribution and direction of the magnetic field near the assembly substrate so that the proper assembly may be performed in the assembly hole of the assembly substrate, thereby controlling the distribution and positional direction of the semiconductor light emitting device, thereby improving the proper assembly rate.

For example, according to the embodiment, the magnetic flux of the magnet is generated horizontally on the assembly substrate so that the LED chip having the magnetic layer is arranged horizontally in the assembly hole of the assembly substrate, thereby improving the proper assembly efficiency in the assembly hole.

Specifically, the embodiment uses a magnet with the N pole and S pole arranged horizontally (horizontal to the X-Y plane) to maintain the magnetic flux in a direction parallel to the assembly substrate, but a magnetic flux (Bz) of the semiconductor light emitting device chip in a vertical direction near the assembly hole can be controlled to be Zero (0). This allows the LED chip with the magnetic layer to be disposed horizontally on the assembly substrate, thereby providing a technical effect of being properly assembled in the assembly hole.

In addition, according to the embodiment, by generating the magnetic flux of the magnet in a horizontal direction on the assembly substrate, the direction of the magnetic flux of the magnetic field applied to the semiconductor light emitting device chip may be controlled, thereby providing a special technical effect of improving the movement speed and assembly speed of the semiconductor light emitting device chip cluster by 2 to 3 times or more compared to the existing internal technology.

In addition, the embodiment may obtain the effect of improving the assembly rate and reducing the number of residual chips or double assembled chips by controlling the strength and direction of the magnetic field applied to the chip by rotating the magnet magnetized with a horizontal magnetic field.

In addition, the embodiment may perform assembly by joining a ferromagnetic metal structure to the magnet part and then rotating the magnet. Accordingly, according to the embodiment, there is a special technical effect that reduces the vertical magnetic flux (Bz) to further reduce the possibility of vertical arrangement of the assembly substrate and the chip, while increasing the horizontal magnetic flux (Bx2) to increase the ratio of horizontal arrangement with the assembly substrate, thereby further increasing the possibility of correct assembly.

The technical effect of the embodiment is not limited to what is described in this item, and includes what may be understood from the description of the invention.

### DESCRIPTION OF DRAWINGS

FIG. 1 is an example diagram of a living room of a house in which a display device according to the embodiment is arranged.

FIG. 2 is a block diagram schematically showing a display device according to the embodiment.

FIG. 3 is a circuit diagram showing an example of a pixel of FIG. 2.

FIG. 4 is an enlarged view of the first panel area in the display device of FIG. 1.

FIG. 5 is a cross-sectional view along the line B1-B2 of the A2 area of FIG. 4.

FIG. 6 is an example of a light emitting device according to an embodiment being assembled on a substrate by a self-assembly method.

FIG. 7 is a partial enlarged view of the A3 area of FIG. 6.

FIG. 8 is a conceptual diagram of rotation and movement of a magnet device in a self-assembly apparatus for a semiconductor light emitting device for a display pixel according to an internal technology.

FIG. 9 is a magnetic flux density data in a magnet device (600) illustrated in FIG. 8.

FIG. 10 is a vertical and horizontal magnetic flux density graph in a magnet device (600) illustrated in FIG. 9.

FIG. 11 is a conceptual diagram of an assembly device (1000) for a semiconductor light emitting device for a display pixel according to an embodiment.

FIG. 12 is an enlarged view and magnetic flux distribution data for an M area in an assembly device (1000) for a semiconductor light emitting device for a display pixel according to an embodiment illustrated in FIG. 11.

FIG. 13 is a magnetic flux density data in the first magnet unit (810) illustrated in FIG. 12.

FIG. 14 is an enlarged view and magnetic flux distribution data of an assembly device (1002) for a semiconductor light emitting device for a display pixel according to the second embodiment.

FIG. 15 is an enlarged perspective view of an assembly device (1003) for a semiconductor light emitting device for a display pixel according to the third embodiment.

FIG. 16 is a magnetic flux distribution data of the third embodiment.

FIG. 17 is an enlarged perspective view of an assembly device (1004) for a semiconductor light emitting device for a display pixel according to the fourth embodiment.

FIG. 18 is an enlarged view and magnetic flux distribution data of an assembly device (1005) for a semiconductor light emitting device for a display pixel according to the fifth embodiment.

### MODE FOR INVENTION

Hereinafter, the embodiments disclosed in this specification will be described in detail with reference to the attached drawings. The suffixes ‘module’ and ‘part’ used for components in the following description are given or used interchangeably for the sake of ease of specification writing, and do not have distinct meanings or roles in themselves. In addition, the attached drawings are intended to facilitate easy understanding of the embodiments disclosed in this specification, and the technical ideas disclosed in this specification are not limited by the attached drawings. In addition, when an element such as a layer, region, or substrate is referred to as existing ‘on’ another element, this includes that it may be directly on the other element or that other intermediate elements may exist between them.

The display devices described in this specification may include digital TVs, mobile phones, smart phones, laptop computers, digital broadcasting terminals, PDAs (personal digital assistants), PMPs (portable multimedia players), navigations, slate PCs, tablet PCs, Ultra-Books, desktop computers, etc. However, the configuration according to the embodiment described in this specification may be applied to a new product type developed in the future, as well as a device capable of display.

The following describes a light emitting device according to an embodiment and a display device including the same.

The following describes an assembly substrate structure of a semiconductor light emitting device display device according to an embodiment and a display device including the same.

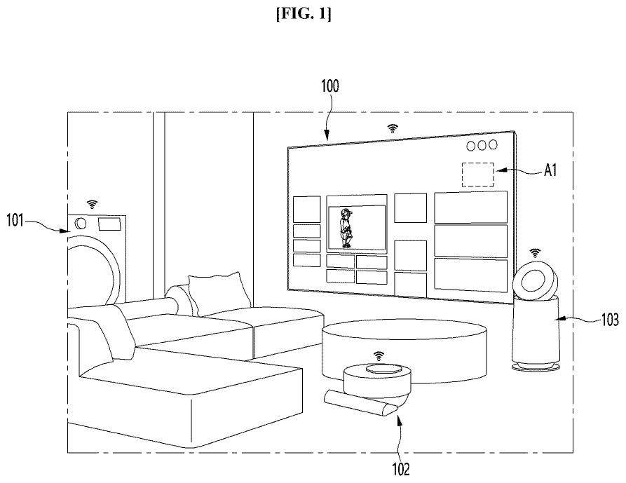

FIG. 1 illustrates a living room of a house in which a display device (100) according to an embodiment is placed.

The display device (100) according to the embodiment may display the status of various electronic products such as a washing machine (101), a robot cleaner (102), and an air purifier (103), and may communicate with each electronic product based on IoT and control each electronic product based on user setting data.

The display device (100) according to the embodiment may include a flexible display manufactured on a thin and flexible substrate. The flexible display may be bent or rolled like paper while maintaining the characteristics of a conventional flat panel display.

In a flexible display, visual information may be implemented by independently controlling the light emission of unit pixels disposed in a matrix form. A unit pixel means a minimum unit for implementing one color. The unit pixel of a flexible display may be implemented by a light emitting device. In an embodiment, the light emitting device may be a Micro-LED or Nano-LED, but is not limited thereto.

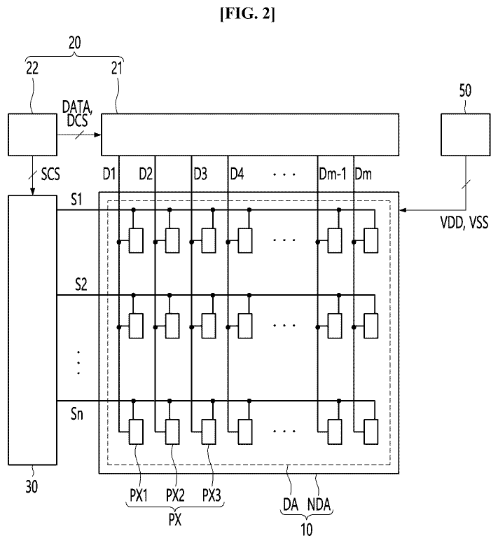

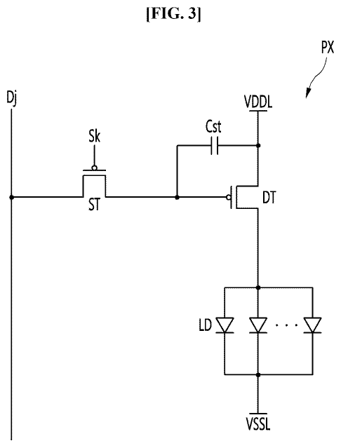

Next, FIG. 2 is a block diagram schematically showing a display device according to an embodiment, and FIG. 3 is a circuit diagram showing an example of a pixel of FIG. 2.

Referring to FIGS. 2 and 3, the display device according to an embodiment may include a display panel (10), a driving circuit (20), a scan driving unit (30), and a power supply circuit (50).

The display device (100) of the embodiment may drive the light emitting element in an active matrix (AM) method or a passive matrix (PM) method.

The driving circuit (20) may include a data driving unit (21) and a timing control unit (22).

The display panel (10) may be divided into a display area (DA) and a non-display area (NDA) arranged around the display area (DA). The display area (DA) is an area where pixels (PX) are formed to display an image. The display panel (10) may include data lines (D1 to Dm, m is an integer greater than or equal to 2), scan lines (S1 to Sn, n is an integer greater than or equal to 2) intersecting the data lines (D1 to Dm), a high-potential voltage line to which a high-potential voltage is supplied, a low-potential voltage line to which a low-potential voltage is supplied, and pixels (PX) connected to the data lines (D1 to Dm) and the scan lines (S1 to Sn).

Each of the pixels (PX) may include a first sub-pixel (PX1), a second sub-pixel (PX2), and a third sub-pixel (PX3). The first sub-pixel (PX1) may emit a first color light of a first wavelength, the second sub-pixel (PX2) may emit a second color light of a second wavelength, and the third sub-pixel (PX3) may emit a third color light of a third wavelength. The first color light may be red light, the second color light may be green light, and the third color light may be blue light, but the present invention is not limited thereto. In addition, although FIG. 2 exemplifies that each of the pixels (PX) includes three sub-pixels, the present invention is not limited thereto. That is, each of the pixels (PX) may include four or more sub-pixels.

Each of the first sub-pixel (PX1), the second sub-pixel (PX2), and the third sub-pixel (PX3) may be connected to at least one of the data lines (D1 to Dm), at least one of the scan lines (S1 to Sn), and a high-potential voltage line. The first sub-pixel (PX1) may include light emitting devices (LD), a plurality of transistors for supplying current to the light emitting devices (LD), and at least one capacitor (Cst), as shown in FIG. 3.

Although not shown in the drawing, each of the first sub-pixel (PX1), the second sub-pixel (PX2), and the third sub-pixel (PX3) may include only one light emitting device (LD) and at least one capacitor (Cst).

Each of the light emitting devices (LD) may be a semiconductor light-emitting diode including a first electrode, a plurality of conductivity type semiconductor layers, and a second electrode. Here, the first electrode may be an anode electrode, and the second electrode may be a cathode electrode, but is not limited thereto.

Referring to FIG. 3, the plurality of transistors may include a driving transistor (DT) that supplies current to the light emitting devices (LD), and a scan transistor (ST) that supplies a data voltage to a gate electrode of the driving transistor (DT). The driving transistor (DT) may include a gate electrode connected to a source electrode of the scan transistor (ST), a source electrode connected to a high-potential voltage line to which a high-potential voltage is applied, and a drain electrode connected to the first electrodes of the light emitting devices (LD). The scan transistor (ST) may include a gate electrode connected to a scan line (Sk, where k is an integer satisfying 1≤k≤n), a source electrode connected to a gate electrode of a driving transistor (DT), and a drain electrode connected to a data line (Dj, where j is an integer satisfying 1≤j≤m).

A capacitor (Cst) is formed between the gate electrode and the source electrode of the driving transistor (DT). The storage capacitor (Cst) may charge the difference between the gate voltage and the source voltage of the driving transistor (DT).

The driving transistor (DT) and the scan transistor (ST) may be formed as thin film transistors. In addition, in FIG. 3, the driving transistor (DT) and the scan transistor (ST) are mainly formed as P-type MOSFETs (Metal Oxide Semiconductor Field Effect Transistors), but the present invention is not limited thereto. The driving transistor (DT) and the scan transistor (ST) may also be formed as N-type MOSFETs. In this case, the positions of the source electrodes and the drain electrodes of each of the driving transistor (DT) and the scan transistor (ST) may be changed.

In addition, in FIG. 3, the first sub-pixel (PX1), the second sub-pixel (PX2), and the third sub-pixel (PX3) are exemplified as including 2TIC (2 Transistors—1 capacitor) having one driving transistor (DT), one scan transistor (ST), and one capacitor (Cst), but the present invention is not limited thereto. Each of the first sub-pixel (PX1), the second sub-pixel (PX2), and the third sub-pixel (PX3) may include a plurality of scan transistors (ST) and a plurality of capacitors (Cst).

Referring again to FIG. 2, the driving circuit (20) outputs signals and voltages for driving the display panel (10). To this end, the driving circuit (20) may include a data driving unit (21) and a timing control unit (22).

The data driving unit (21) receives digital video data (DATA) and a source control signal (DCS) from the timing control unit (22). The data driving unit (21) converts the digital video data (DATA) into analog data voltages according to the source control signal (DCS) and supplies the same to the data lines (D1 to Dm) of the display panel (10).

The timing control unit (22) receives digital video data (DATA) and timing signals from the host system. The timing signals may include a vertical sync signal, a horizontal sync signal, a data enable signal, and a dot clock. The host system may be an application processor of a smartphone or tablet PC, a monitor, a system on chip of a TV, etc.

The scan driving unit (30) receives a scan control signal (SCS) from the timing control unit (22). The scan driving unit (30) generates scan signals according to the scan control signal (SCS) and supplies them to the scan lines (S1 to Sn) of the display panel (10). The scan driving unit (30) may include a plurality of transistors and may be formed in a non-display area (NDA) of the display panel (10). Alternatively, the scan driving unit (30) may be formed as an integrated circuit, in which case it may be mounted on a gate flexible film attached to the other side of the display panel (10).

The power supply circuit (50) may generate a high-potential voltage (VDD) and a low-potential voltage (VSS) for driving the light emitting devices (LD) of the display panel (10) from the main power supply and supply them to the high-potential voltage line and the low-potential voltage line of the display panel (10). In addition, the power supply circuit (50) may generate and supply driving voltages for driving the driving circuit (20) and the scan driving unit (30) from the main power supply.

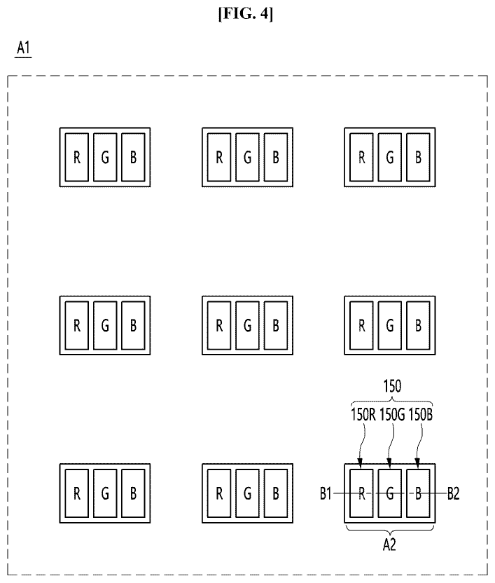

Next, FIG. 4 is an enlarged view of the first panel area (A1) in the display device of FIG. 1.

According to FIG. 4, the display device (100) of the embodiment may be manufactured by mechanically and electrically connecting a plurality of panel areas such as the first panel area (A1) by tiling.

The first panel area (A1) may include a plurality of light emitting devices (150) arranged for each unit pixel (PX of FIG. 2).

For example, a unit pixel (PX) may include a first sub-pixel (PX1), a second sub-pixel (PX2), and a third sub-pixel (PX3). For example, a plurality of red light emitting devices (150R) may be disposed in a first sub-pixel (PX1), a plurality of green light emitting devices (150G) may be disposed in a second sub-pixel (PX2), and a plurality of blue light emitting devices (150B) may be disposed in a third sub-pixel (PX3). The unit pixel (PX) may further include a fourth sub-pixel in which no light emitting devices are arranged, but this is not limited thereto. Meanwhile, the light emitting device (150) may be a semiconductor light emitting device.

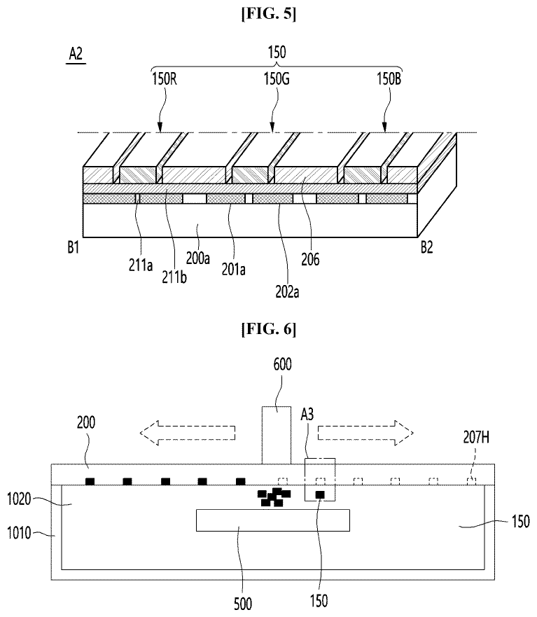

Next, FIG. 5 is a cross-sectional view along the line B1-B2 of the A2 region of FIG. 4.

Referring to FIG. 5, the display device (100) of the embodiment may include a substrate (200a), spaced wiring (201a, 202a), a first insulating layer (211a), a second insulating layer (211b), a third insulating layer (206), and a plurality of light emitting devices (150).

The wiring may include a first wiring (201a) and a second wiring (202a) spaced from each other. The first wiring (201a) and the second wiring (202a) may function as panel wiring for applying power to the light emitting devices (150) in the panel, and may also function as assembly electrodes for generating a dielectric force for assembling in the case of self-assembly of the light emitting devices (150).

The wiring (201a, 202a) may be formed of a transparent electrode (ITO) or may include a metal material having excellent electrical conductivity. For example, the wiring (201a, 202a) may be formed of at least one of titanium (Ti), chromium (Cr), nickel (Ni), aluminum (Al), platinum (Pt), gold (Au), tungsten (W), and molybdenum (Mo), or an alloy thereof.

A first insulating layer (211a) may be disposed between the first wiring (201a) and the second wiring (202a), and a second insulating layer (211b) may be disposed on the first wiring (201a) and the second wiring (202a). The first insulating layer (211a) and the second insulating layer (211b) may be an oxide film, a nitride film, or the like, but are not limited thereto.

The light emitting device (150) may include a red light emitting device (150R), a green light emitting device (150G), and a blue light emitting device (150B0 to form a unit pixel (sub-pixel), but is not limited thereto, and may implement red and green colors respectively by providing a red fluorescent substance and a green fluorescent substance.

The substrate (200a) may be formed of glass or polyimide. In addition, the substrate (200a) may include a flexible material such as PEN (Polyethylene Naphthalate) or PET (Polyethylene Terephthalate). In addition, the substrate (200) may be a transparent material, but is not limited thereto. The substrate (200a) may function as a support substrate in the panel, and may also function as an assembly substrate when self-assembling the light emitting device.

The third insulating layer (206) may be formed of an insulating and flexible material such as polyimide, PEN, PET, etc. It may include a material, and may be formed integrally with the substrate (200a) to form a single substrate.

The third insulating layer (206) may be a conductive adhesive layer having adhesiveness and conductivity, and the conductive adhesive layer may be flexible to enable a flexible function of the display device. For example, the third insulating layer (206) may be a conductive adhesive layer such as an anisotropic conductive film (ACF) or an anisotropic conductive medium, a solution containing conductive particles, etc. The conductive adhesive layer may be a layer that is electrically conductive in a vertical direction with respect to the thickness, but electrically insulating in a horizontal direction with respect to the thickness.

The interval between the first and second wirings (201a, 202a) is formed less than the width of the light emitting device (150) and the width of the assembly hole (207H), so that the assembly position of the light emitting device (150) using an electric field may be more precisely fixed.

The first and second A third insulating layer (206) is formed on the wiring (201a, 202a) to protect the first and second wirings (201a, 202a) from the fluid (1020) and prevent leakage of current flowing in the first and second wirings (201a, 202a). The third insulating layer (206) may be formed as a single layer or multiple layers of an inorganic insulator such as silica or alumina or an organic insulator.

In addition, the third insulating layer (206) may include an insulating and flexible material such as polyimide, PEN, PET, etc., and may be formed integrally with the substrate (200) to form a single substrate.

The third insulating layer (206) may have a partition wall, and an assembly hole (207H) may be formed by the partition wall. For example, the third insulating layer (206) may be formed as an assembly hole for inserting a light emitting device (150). may include a hole (207H) (see FIG. 6). Therefore, during self-assembly, the light emitting device (150) may be easily inserted into the assembly hole (207H) of the third insulating layer (206). The assembly hole (207H) may be called an insertion hole, a fixing hole, an alignment hole, etc.

The assembly hole (207H) may have a shape and size corresponding to the shape of the light emitting device (150) to be assembled at the corresponding position. Accordingly, it is possible to prevent another light emitting device from being assembled in the assembly hole (207H) or a plurality of light emitting devices from being assembled.

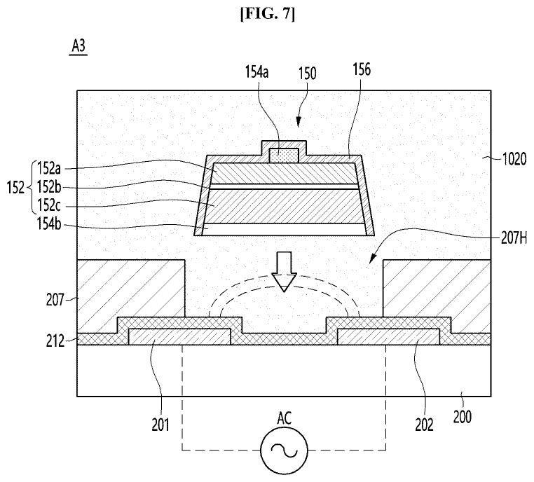

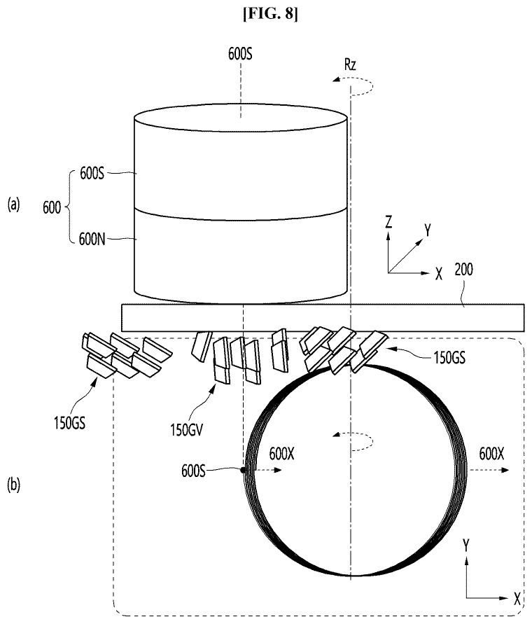

Next, FIG. 6 is a drawing showing an example of a light emitting device according to an embodiment being assembled to a substrate by a self-assembly method, and FIG. 7 is a partial enlarged view of the A3 area of FIG. 6. FIG. 7 is a drawing in which the A3 area is rotated 180 degrees for convenience of explanation.

Referring to FIG. 6 and FIG. 7, hereinafter, an example of assembling a semiconductor light emitting device according to an embodiment into a display panel by a self-assembly method using an electromagnetic field will be described.

The assembly substrate (200) described below may also function as a panel substrate (200a) in a display device after assembling the light emitting device, but the embodiment is not limited thereto.

Referring to FIG. 6, the semiconductor light emitting device (150) may be inserted into the chamber (1010) filled with a fluid (1020) and the semiconductor light emitting device (150) may move to the assembly substrate (200) while forming a cluster of semiconductor light emitting devices (150G) by the magnetic field generated from the magnetic magnet device (600). At this time, the light emitting device (150) adjacent to the assembly hole (207H) of the assembly substrate (200) may be assembled into the assembly hole (207H) by the DEP force by the electric field of the assembly electrodes. The fluid (1020) may be water such as ultrapure water, but is not limited thereto. The chamber may be called a tank, a container, a vessel, etc.

After the semiconductor light emitting device (150) is inserted into the chamber (1010), the assembly substrate (200) may be placed on the chamber (1010). Depending on the embodiment, the assembly substrate (200) may also be inserted into the chamber (1010).

In the internal technology, a chip tray (500) is placed in an assembly chamber, semiconductor light emitting device chips (150G) are supplied to the chip tray, and then semiconductor light emitting devices are uniformly provided to the assembly substrate using the chip tray (500) to improve assembly efficiency.

Next, referring to FIG. 7, the semiconductor light emitting device (150) may be implemented as a vertical semiconductor light emitting device as shown, but is not limited thereto, and a horizontal light emitting device may be employed.

The semiconductor light emitting device (150) may include a magnetic layer (154b) having a magnetic body. The magnetic layer (154b) may include a metal having magnetism, such as nickel, cobalt, or iron. Since the semiconductor light emitting device (150) injected into the fluid includes the magnetic layer (154b), it may move to the assembly substrate (200) by a magnetic field generated from the magnet device (600).

The semiconductor light emitting device (150) may include a passivation layer (156) surrounding the upper surface and the side surface. The passivation layer (156) may be formed by an inorganic insulator such as silica or alumina through PECVD, LPCVD, sputtering deposition, etc. In addition, the passivation layer (156) may be formed by a method of spin coating an organic material such as photoresist or a polymer material.

The semiconductor light emitting device (150) may include a first conductivity type semiconductor layer (152a), a second conductivity type semiconductor layer (152c), and an active layer (152b) disposed therebetween. The first conductivity type semiconductor layer (152a) may be a n-type semiconductor layer, and the second conductivity type semiconductor layer (152c) may be a p-type semiconductor layer, but is not limited thereto.

A first electrode layer (154a) may be disposed on the first conductivity type semiconductor layer (152a), and a second electrode layer (not shown) may be disposed on the second conductivity type semiconductor layer (152c). To this end, a portion of the first conductivity type semiconductor layer (152a) or the second conductivity type semiconductor layer may be exposed to the outside. The magnetic layer (154b) may be disposed above or below the second electrode layer. After the semiconductor light emitting device (150) is assembled on the assembly substrate (200), a portion of the passivation layer (156) may be etched in the manufacturing process of the display device.

The assembly substrate (200) may include a pair of first assembly electrodes (201) and second assembly electrodes (202) corresponding to each of the semiconductor light emitting devices (150) to be assembled. The first assembly electrode (201) and the second assembly electrode (202) may be formed by laminating multiple single metals or metal alloys, metal oxides, etc. For example, the first assembly electrode (201) and the second assembly electrode (202) may be formed by including at least one of Cu, Ag, Ni, Cr, Ti, Al, Rh, Pd, Ir, Ru, Mg, Zn, Pt, Au, and Hf, but are not limited thereto.

In addition, the first assembly electrode (201) and the second assembly electrode (202) may be formed by including at least one of ITO (indium tin oxide), IZO (indium zinc oxide), IZTO (indium zinc tin oxide), IAZO (indium aluminum zinc oxide), IGZO (indium gallium zinc oxide), IGTO (indium gallium tin oxide), AZO (aluminum zinc oxide), ATO (antimony tin oxide), GZO (gallium zinc oxide), IZON (IZO Nitride), AGZO (Al—Ga ZnO), IGZO (In—Ga ZnO), ZnO, IrOx, RuOx, NiO, RuOx/ITO, Ni/IrOx/Au, and Ni/IrOx/Au/ITO, but are not limited thereto.

The first assembly electrode (201) and the second assembly electrode (202) may fix the semiconductor light emitting device (150) inserted into the assembly hole (207H) by the dielectric force by emitting an electric field when an AC voltage is applied. The gap between the first assembly electrode (201) and the second assembly electrode (202) may be less than the width of the semiconductor light emitting device (150) and the width of the assembly hole (207H), and the assembly position of the semiconductor light emitting device (150) may be fixed more precisely using the electric field.

An insulating layer (212) is formed on the first assembly electrode (201) and the second assembly electrode (202), thereby protecting the first assembly electrode (201) and the second assembly electrode (202) from the fluid (1020) and preventing leakage of current flowing through the first assembly electrode (201) and the second assembly electrode (202). For example, the insulating layer (212) may be formed as a single layer or multiple layers of an inorganic insulator such as silica or alumina, or an organic insulator. The insulating layer (212) may have a minimum thickness to prevent damage to the first assembly electrode (201) and the second assembly electrode (202) when assembling the semiconductor light emitting device (150), and may have a maximum thickness to stably assemble the semiconductor light emitting device (150).

A partition wall (207) may be formed on the upper portion of the insulating layer (212). Some areas of the partition wall (207) may be located on the upper portion of the first assembly electrode (201) and the second assembly electrode (202), and the remaining areas may be located on the upper portion of the assembly substrate (200).

Meanwhile, when manufacturing the assembly substrate (200), some of the partition walls formed over the entire upper portion of the insulating layer (212) are removed, so that an assembly hole (207H) in which each of the semiconductor light emitting devices (150) is coupled and assembled to the assembly substrate (200) may be formed.

An assembly hole (207H) in which the semiconductor light emitting devices (150) are coupled is formed in the assembly substrate (200), and a surface on which the assembly hole (207H) is formed may come into contact with a fluid (1020). The assembly hole (207H) may guide the exact assembly position of the semiconductor light emitting device (150).

Meanwhile, the assembly hole (207H) may have a shape and size corresponding to the shape of the semiconductor light emitting device (150) to be assembled at the corresponding position. Accordingly, it is possible to prevent another semiconductor light emitting device from being assembled in the assembly hole (207H) or a plurality of semiconductor light emitting devices from being assembled.

Referring back to FIG. 6, after the assembly substrate (200) is immersed in the fluid of the chamber, a magnet device (600) that applies a magnetic field may move along the assembly substrate (200). The magnet device (600) may be a permanent magnet such as a neodymium magnet or an electromagnet.

The magnet device (600) may move in contact with the assembly substrate (200) to maximize the area affected by the magnetic field into the fluid (1020). Depending on the embodiment, the magnet device (600) may include a plurality of magnetic bodies or may include magnetic bodies of a size corresponding to the assembly substrate (200). In this case, the movement distance of the magnet device (600) may be limited to a predetermined range.

The semiconductor light emitting device (150) in the chamber (1010) may move toward the magnet device (600) and the assembly substrate (200) by the magnetic field generated by the magnet device (600).

Referring to FIG. 7, the semiconductor light emitting device (150) may be fixed by entering the assembly hole (207H) by the dielectrophoretic force (DEP force) formed by the electric field of the assembly electrode of the assembly substrate while moving toward the magnet device (600).

Specifically, the first and second assembly wirings (201, 202) form an electric field by the AC power, and the dielectrophoretic force may be formed between the assembly wirings (201, 202) by this electric field. The semiconductor light emitting device (150) may be fixed to the assembly hole (207H) on the assembly substrate (200) by this dielectrophoretic force.

At this time, a predetermined solder layer (not shown) may be formed between the light emitting device (150) assembled on the assembly hole (207H) of the assembly substrate (200) and the assembly electrode to improve the bonding strength of the light emitting device (150).

In addition, a molding layer (not shown) may be formed on the assembly hole (207H) of the assembly substrate (200) after assembly. The molding layer may be a transparent resin or a resin containing a reflective material or a scattering material.

By the self-assembly method using the electromagnetic field described above, the time required for each semiconductor light emitting device to be assembled on the substrate may be drastically shortened, so that a large-area, high-pixel display may be implemented more quickly and economically.

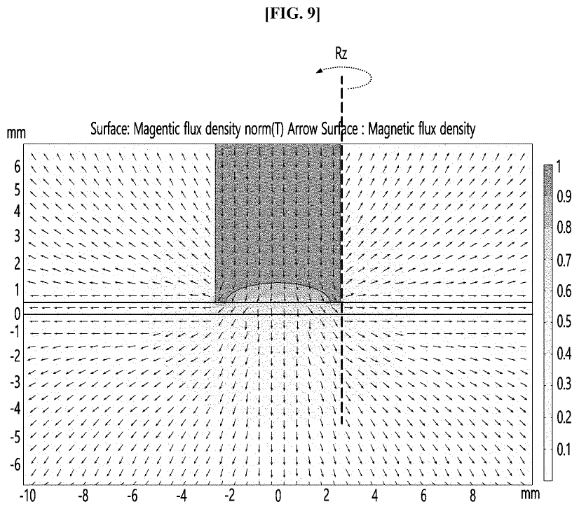

First, technical problems in self-assembly of semiconductor light emitting devices for display pixels according to internal technology will be explained with reference to FIGS. 8 to 10.

FIG. 8 is a vertical perspective view (see FIG. 8(a)) of a rotating magnet device (600) disposed on an assembly substrate (200) in a self-assembly apparatus for a semiconductor light emitting device for a display pixel according to an internal technology, and a planar conceptual diagram for the rotation and movement (600X) of the magnet device (600) (see FIG. 8(b)).

Referring to FIG. 8(a), in the self-assembly apparatus for a semiconductor light emitting device for a display pixel according to an internal technology, the magnet device (600) is illustrated as an example of a permanent magnet, includes an N-pole magnet region (600A) and a S-pole magnet region (600B), and may rotate around a predetermined rotation axis (Rz).

Referring to (b) of FIG. 8, the magnet device (600) may move in the first direction (600X) of the X-axis while the center (600S) of the magnet rotates counterclockwise (or clockwise) around the rotation axis (Rz).

Meanwhile, according to the internal technology, the magnetic force of the magnet was limited to moving the semiconductor light emitting devices to the vicinity of the assembly hole of the assembly substrate, and it was not studied whether the arrangement direction of the semiconductor light emitting devices positioned near the assembly hole by the magnetic force was suitable for assembling into the assembly hole.

For example, according to the internal technology, semiconductor light emitting devices (150GV) arranged vertically on the assembly substrate (200) are generated in the central axis (600S) area of the rotating magnet device (600) by the magnetic force generated by the rotating magnet device (600), and inclined semiconductor light emitting devices (150GS) are generated in the outer boundary area of the rotating magnet device (600).

Vertically arranged semiconductor light emitting devices (150GV) or inclined semiconductor light emitting devices (150GS) are not suitable for assembling in the assembly hole.

In addition to being difficult to assemble properly in a vertical or inclined state, incorrect assembly occurs in which two to three multiple chips are assembled.

In addition, according to the internal technology, a cluster of semiconductor light emitting devices chips is formed by a rotating magnet device (600), and vertically arranged chips may experience friction with the assembly substrate due to Bz (vertical magnetic field), and fluid resistance of the chips may occur when the chip cluster moves, which reduces the mobility of the chip cluster.

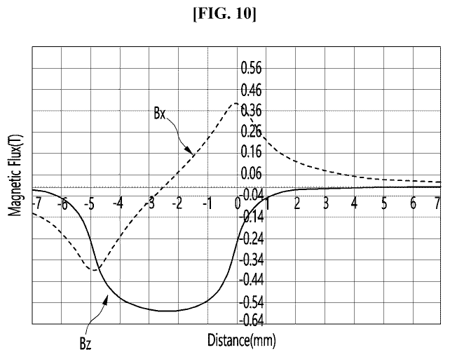

Next, FIG. 9 is the magnetic flux density data in the magnet device (600) illustrated in FIG. 8, and FIG. 10 is a vertical and horizontal magnetic flux density graph in the magnet device (600) illustrated in FIG. 9.

Specifically, FIG. 10 is a graph of the magnetic flux density (Bz) in the Z-axis direction (vertical direction) and the horizontal magnetic flux density (Bx) data in the magnet device (600) illustrated in FIG. 9.

In the case of the rotating magnet of the existing internal technology, the concept is that a single magnet rotates and moves in a clockwise or counterclockwise direction, and this makes it difficult to improve the mobility of the LED chip cluster compared to the same rotation speed.

Specifically, in the self-assembly equipment according to the internal technology, a cluster of semiconductor light emitting devices including a magnetic layer is moved by a large number of rotating magnet rods, and the semiconductor light emitting devices are assembled into the assembly holes of the assembly substrate.

However, the method of supplying LED chips to the assembly substrate in the self-assembly equipment of the existing internal technology uses a method in which an LED chip with a magnetic layer is located on the lower side of the assembly substrate, a rotating magnet is positioned on the upper side of the assembly substrate, the rotating magnet is moved in the X and Y horizontal directions to move the LED chip near the assembly hole of the assembly substrate, and then a DEP force is applied to assemble the LED chips into the assembly hole of the assembly substrate.

However, the rotating magnet of the existing internal technology is a concept of moving by rotating clockwise or counterclockwise, and this method may have a difficulty in improving the mobility of the LED chip cluster compared to the rotation speed.

In particular, according to the internal technology, the state of the individual LED chips in the LED chip cluster moved near the assembly hole of the assembly substrate by the rotating magnet is arranged and positioned in the direction of the magnetic flux of the magnet in the fluid.

For example, referring to FIGS. 9 and 10, since the vertical magnetic flux (Bz) is maintained at a considerable level, when the LED chips are positioned vertically (150GV) or tilted (150GS) on the assembly substrate as in FIG. 8, an assembly defect occurs in which 2 to 3 LED chips in the vertical state are assembled at once by the assembly hole.

In addition, when the LED chip cluster moves due to the vertical magnetic field (Bz) of the rotating magnet, fluid resistance may occur depending on the distribution shape of the chips.

Hereinafter, a magnet assembly device for a semiconductor light emitting device for a pixel and a self-assembly apparatus for a semiconductor light emitting device for a display pixel including the same according to an embodiment for solving the above technical problem will be described.

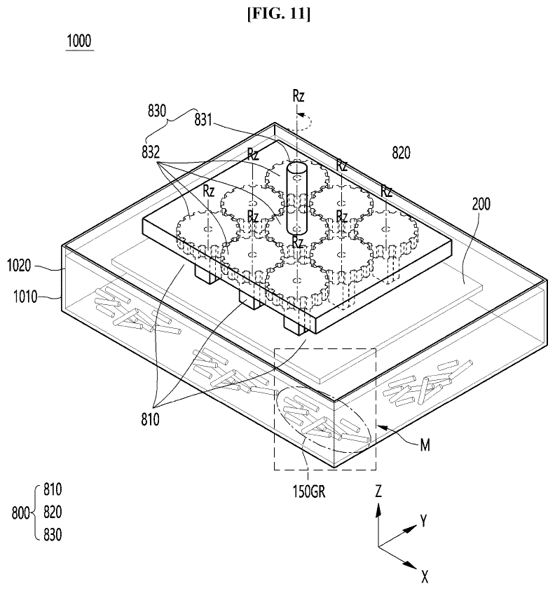

FIG. 11 is a conceptual diagram of an assembly device (1000) for a semiconductor light emitting device for a display pixel according to an embodiment.

The assembly device (1000) of a semiconductor light emitting device for a display pixel according to an embodiment may include a chamber (1010), a fluid (1020) in which a cluster of semiconductor light emitting devices (150GR) is dispersed, an assembly substrate (200), and a magnet assembly device (800).

The magnet assembly device (800) may include a first magnet unit (810), a support member (820), and a magnet rotation member (830).

The magnet rotation member (830) may include a magnet driving member (831) and a single or multiple magnet gear members (832).

For example, the magnet gear member (832) may be a gear in the form of a gear wheel.

Each magnet gear member (832) may be equipped with a first magnet unit (810).

The first magnet unit (810) may be disposed at an eccentricity of each magnet gear part (832).

For example, the center of the first magnet unit (810) may be disposed at a position off the center of each magnet gear part (832).

Accordingly, when the magnet gear part (832) rotates, the first magnet unit (810) may rotate with a wide rotation radius greater than the diameter of the first magnet unit (810), thereby expanding the distribution range of the magnetic force.

In the embodiment, a plurality of magnet gear parts (832) may be engaged by the rotation of the magnet driving part (831), and the individual magnet gear parts (832) may be rotated in a chain.

Accordingly, the magnet driving unit (831) rotates around the rotation axis (Rz), so that the plurality of first magnet units (810) may be simultaneously and individually rotated around their respective rotation axes (Rz), but is not limited thereto.

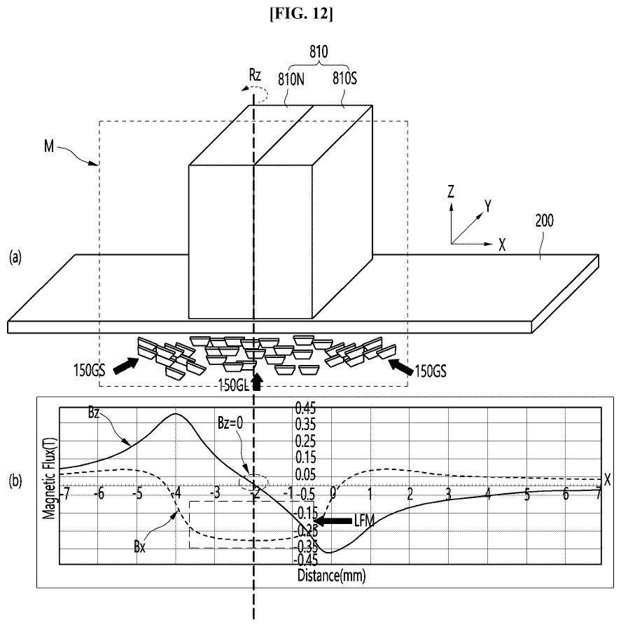

Next, FIG. 12 is an enlarged view and magnetic flux distribution data for the M region in the assembly device (1000) of the semiconductor light emitting device for display pixels according to the embodiment illustrated in FIG. 11. The M region may be an area including the first magnet unit (810) and the semiconductor light emitting device cluster (150GR).

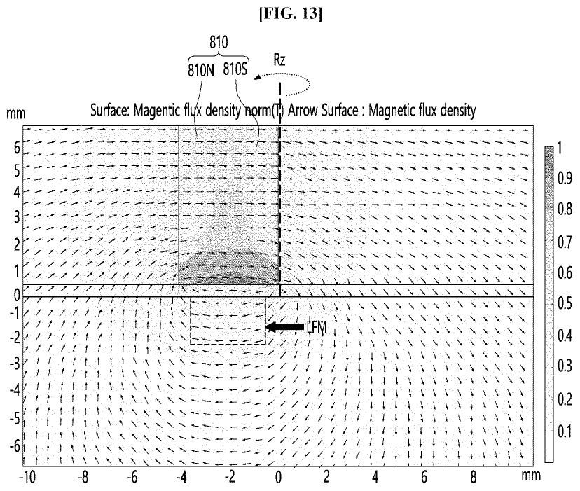

In addition, FIG. 13 is magnetic flux density data in the first magnet unit (810) illustrated in FIG. 12.

Referring to FIG. 12, the first magnet unit (810) of the embodiment may include a N-pole magnet region (810N) and a S-pole magnet region (810S) and may rotate around a predetermined rotation axis (Rz). The rotation axis (Rz) may be the center axis of the magnet gear part (832), but is not limited thereto.

In addition, the rotation axis (Rz) may be disposed at the outer region of the boundary between the N-pole magnet region (810N) and the S-pole magnet region (810S), but is not limited thereto.

The first magnet unit (810) of the embodiment may be a permanent magnet or an electromagnet.

In the first magnet unit (810) of the embodiment, the magnetization direction, which is the magnetization direction of the N-pole magnet region (810N) and the S-pole magnet region (810S), may be disposed in a horizontal direction of the assembly substrate (200).

For example, in the first magnet unit (810), the magnetization direction, which is the magnetization direction of the N-pole magnet region (810N) and the S-pole magnet region (810S), may be disposed in a horizontal direction parallel to the XY plane direction of the assembly substrate (200).

In addition, in the first magnet unit (810), the magnetization direction, which is the magnetization direction of the N-pole magnet region (810N) and the S-pole magnet region (810S), may be disposed in a horizontal direction on the surface of the magnet gear part (832).

In the embodiment, the first magnet unit (810) may be a square magnet structure including an N-pole magnet region (810N) and a S-pole magnet region (810S), but is not limited thereto.

According to the embodiment, the magnetic flux of the first magnet unit (810) is generated horizontally on the assembly substrate (200) so that the LED chip having the magnetic layer is arranged horizontally in the assembly hole of the assembly substrate, thereby improving the assembly efficiency in the assembly hole.

Specifically, the embodiment uses the first magnet unit (810) in which the N-pole and the S-pole are arranged horizontally (horizontal to the X-Y plane) so that the magnetic flux is maintained in a direction parallel to the assembly substrate, but the vertical magnetic flux (Bz) becomes zero (0) near the assembly hole. Through this, the LED chip having the magnetic layer is arranged horizontally on the assembly substrate (150GL), thereby providing the technical effect of being properly assembled in the assembly hole.

Also, according to the embodiment, the horizontal direction magnetic flux (Bx) is maximized in the magnetic flux area of the first magnet unit (810), so that the magnetic layer of the semiconductor light emitting device is arranged along the horizontal direction magnetic flux (Bx), thereby increasing the correct assembly rate.

Referring to FIG. 13, according to the embodiment, the magnetization direction, which is the magnetization direction of the N-pole magnet area (810N) and the S-pole magnet area (810S) of the first magnet unit (810), is disposed in the horizontal direction of the assembly substrate (200), so that the direction of the magnetic flux generated from the first magnet unit (810) is controlled in the horizontal direction (LFM), so that the arrangement state of the semiconductor light emitting device in the semiconductor light emitting device chip cluster may be controlled parallel to the assembly substrate.

Referring again to FIG. 12, according to the embodiment, a horizontal magnetic flux region (LMF) in which a vertical magnetic field (Bz) becomes zero (0) within a predetermined magnetic flux density range corresponding to the size of the cluster of semiconductor light emitting devices in the first magnet unit (810) of the embodiment may be formed, thereby significantly improving the assembly efficiency in the assembly hole.

In addition, there is a special technical effect that can improve the speed of the regular assembly by 2 to 3 times or more compared to the existing internal technology.

For example, according to the embodiment, since the magnetic layer of the semiconductor light emitting device may take a horizontal form (150GL) with respect to the assembly hole rather than a form in which the semiconductor light emitting device chip is tilted (150GS) in the assembly hole of the assembly substrate due to the magnetic field distribution, the assembly rate of the semiconductor light emitting device chip can be significantly improved by the DEP force.

In addition, according to the embodiment, there is a technical effect in that, unlike the conventional internal technology, there is almost no form (150GV) that is vertically erected on the assembly board.

In addition, according to the embodiment, the direction of the magnetic flux of the magnetic field applied to the semiconductor light emitting device chip is controlled in the horizontal direction (LFM), thereby controlling the arrangement state of the semiconductor light emitting devices in the semiconductor light emitting device chip cluster to be parallel to the assembly substrate, thereby reducing the resistance with the fluid and the resistance with the assembly substrate, thereby improving the moving speed of the semiconductor light emitting device chip cluster by 2 to 3 times or more compared to the conventional internal technology.

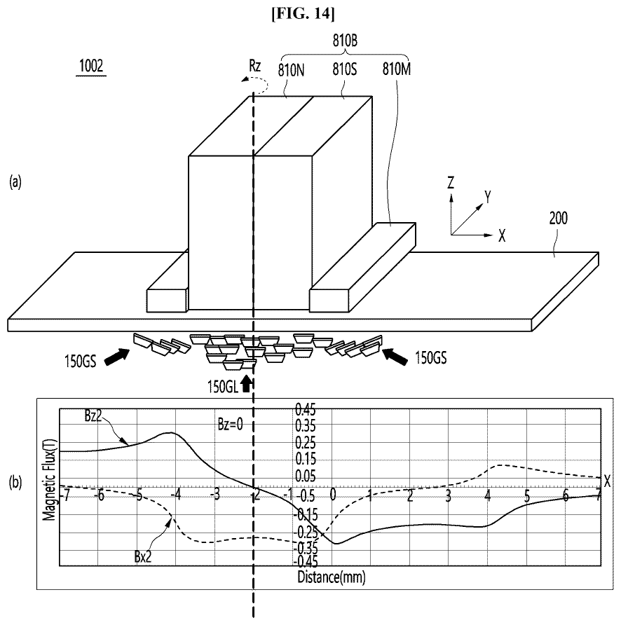

Next, FIG. 14 is an enlarged view and magnetic flux distribution data of the assembly device (1002) of the semiconductor light emitting device for display pixels according to the second embodiment.

The assembly device (1002) of the semiconductor light emitting device for display pixels according to the second embodiment may adopt the technical features of the assembly device (1000) of the semiconductor light emitting device for display pixels according to the first embodiment, and the features of the second embodiment will be described below.

The second magnet unit (810B) of the second embodiment may further include a metal part (810M) on one or both sides of the N-pole magnet region (810N) and the S-pole magnet region (810S).

The metal part (810M) may include ferromagnetic materials such as ferrite, nickel, iron, cobalt, nickel-cobalt, or an alloy thereof.

According to the second embodiment, the distribution of a magnetic field formed in the vicinity of an assembly substrate may be controlled by bonding a metal part (810M) that is a ferromagnetic material to one or both sides of the N-pole magnet region (810N) and the S-pole magnet region (810S).

For example, referring to FIG. 14 (b), in the second embodiment, the vertical magnetic flux (Bz2) has the effect of being lower than the vertical magnetic flux (Bz) of the first embodiment, FIG. 12 (b), and the horizontal magnetic flux (Bx2) of the second embodiment has the effect of being higher than the vertical magnetic flux (Bx) of the first embodiment, FIG. 12 (b).

Accordingly, according to the second embodiment, the vertical magnetic flux (Bz) is reduced to further reduce the possibility of the assembly substrate and the chip being vertically arranged, while on the other hand, the horizontal magnetic flux (Bx2) is increased to increase the ratio of being horizontally arranged with the assembly substrate, thereby further increasing the possibility of correct assembly.

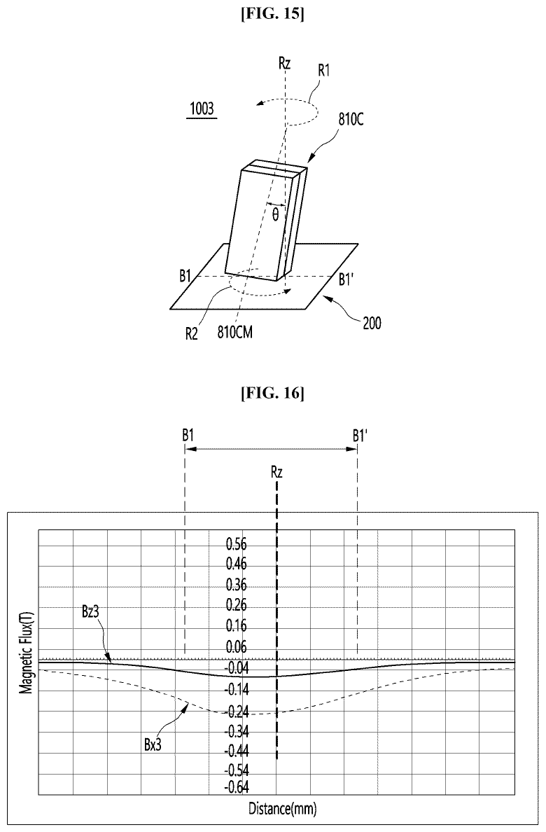

Next, FIG. 15 is an enlarged perspective view of an assembly device (1003) for a semiconductor light emitting device for a display pixel according to the third embodiment, and FIG. 16 is the magnetic flux distribution data of the third embodiment.

The third embodiment may adopt the technical features of the first embodiment or the second embodiment, and the following description will focus on the features of the third embodiment.

The third magnet unit (810C) of the third embodiment may be rotated in a tilted state at a predetermined angle (θ) with respect to the rotation axis (Rz).

For example, the central axis (810 CM) of the third magnet unit (810C) may be rotated in a tilted state at a predetermined angle (θ) with respect to the rotation axis (Rz).

For example, the angle (θ) between the central axis (810 CM) of the third magnet unit (810C) and the rotation axis (Rz) may be 60° or less.

For example, when the angle (θ) between the central axis (810 CM) of the third magnet unit (810C) and the rotation axis (Rz) may be tilted by 1° to 45°, the size of the magnetic field may increase toward the center of the rotation axis (Rz), so that the semiconductor light emitting device cluster may be well formed around the rotation axis, and also, depending on the degree of inclination of the magnet, there is a special technical effect in that the magnetic field distribution near the assembly substrate may be additionally controlled to control the shape of the motion state of the individual chip.

For example, referring to FIG. 15, the first rotation radius (R1) on the upper side and the second rotation radius (R2) on the lower side of the third magnet unit (810C) may be different from each other.

For example, the first rotation radius (R1) on the upper side of the third magnet unit (810C) may be less than the second rotation radius (R2) on the lower side.

In the third embodiment, the rotation of the third magnet unit (810C) maximizes the size of the second rotation radius (R2) adjacent to the assembly substrate (200) to expand the area of the horizontal magnetic flux, thereby improving the assembly efficiency.

Next, referring to FIG. 16, in the third embodiment, there is an effect of significantly reducing the vertical magnetic flux (Bz3).

According to the third embodiment, when the central axis (810 CM) of the third magnet unit (810C) and the rotation axis (Rz) are rotated in an inclined state, the distribution (at center) of the magnetic field on the surface of the assembly substrate moves away from the rotation axis (Rz), and accordingly, the size of the cluster may be controlled for the same amount of chips.

In addition, according to the third embodiment, when the center axis (810 CM) of the third magnet unit (810C) and the rotation axis (Rz) are rotated in an inclined state, there is an effect that the vertical magnetic flux (Bz3) can be significantly reduced.

In particular, in the third embodiment, the magnetic field distribution near the assembly substrate may be induced diagonally according to the lower side of the third magnet unit (810) from the surface of the assembly substrate.

Therefore, the position distribution of the chip itself may be distributed slightly diagonally by the magnetic field arranged diagonally, and accordingly, there is a special technical effect that the probability of the semiconductor light emitting device being assembled into the assembly hole as if sliding increases.

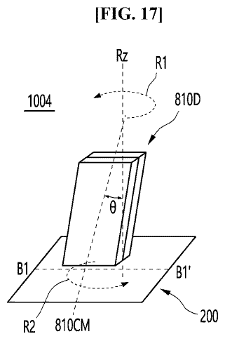

Next, FIG. 17 is an enlarged perspective view of an assembly device (1004) for a semiconductor light emitting device for a display pixel according to the fourth embodiment.

The fourth embodiment may adopt the technical features of the first to third embodiments, and the following description will focus on the features of the fourth embodiment.

In the fourth embodiment, the vertical cross-section of the fourth magnet unit (810D) may be in the form of a parallelogram. Accordingly, the upper surface of the fourth magnet unit (810D) may be parallel to the surface of the gear portion (832) on which the fourth magnet unit (810D) is mounted.

In addition, the lower surface of the fourth magnet unit (810D) may be parallel to the surface of the assembly substrate (200).

Therefore, since the vertical cross-section of the fourth magnet unit (810D) includes the form of a parallelogram, there is a composite technical effect in which the assembly with the gear portion (832) is solid and a horizontal magnetic field may be efficiently formed in the direction of the assembly substrate (200).

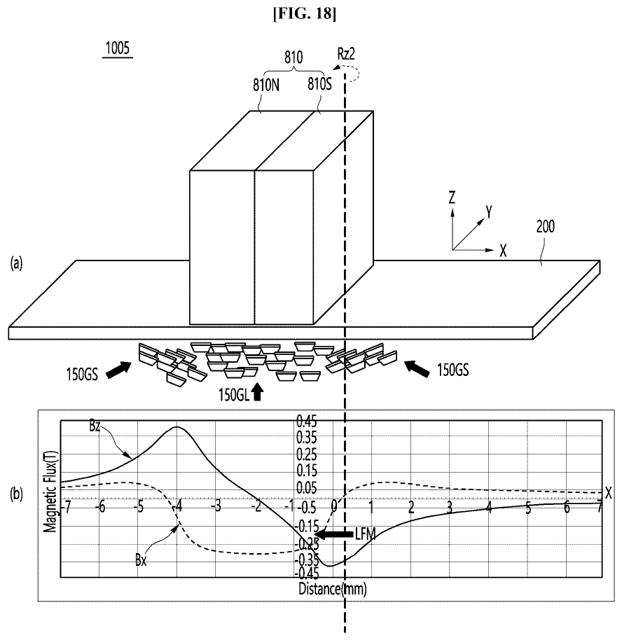

FIG. 18 is an enlarged view and magnetic flux distribution data of an assembly device (1005) of a semiconductor light emitting device for a display pixel according to the fifth embodiment.

The fifth embodiment may adopt the technical features of the first to fourth embodiments, and the following description will focus on the features of the fifth embodiment.

Referring briefly to FIG. 12, the first magnet unit (810) may include a N-pole magnet region (810N) and a S-pole magnet region (810S), and the rotation axis (Rz) may be disposed at an outer region of a boundary between the N-pole magnet region (810N) and the S-pole magnet region (810S).

On the other hand, referring to FIG. 18, in the fifth embodiment, the second rotation axis (Rz2) may be disposed at the outer region of the N-pole magnet region (810N) or the outer region of the S-pole magnet region (810S) of the first magnet unit (810).

For example, in the fifth embodiment, the second rotation axis (Rz2) may be disposed at the outer region of the N-pole magnet region (810N) or the outer region of the S-pole magnet region (810S) rather than the outer region of the boundary between the N-pole magnet region (810N) and the S-pole magnet region (810S) of the first magnet unit (810).

According to the embodiment, the magnetic flux of the magnet may be generated horizontally on the assembly substrate so that the LED chip having the magnetic layer may be arranged horizontally in the assembly hole of the assembly substrate, thereby improving the assembly efficiency in the assembly hole.

Specifically, the embodiment may maintain the magnetic flux in the direction parallel to the assembly substrate by using a magnet with the N pole and S pole arranged horizontally (horizontal to the X-Y plane), but the vertical magnetic flux (Bz) becomes zero (0) near the assembly hole. This has the technical effect of allowing the LED chip with the magnetic layer to be disposed horizontally on the assembly substrate and properly assembled in the assembly hole.

The above detailed description should not be construed as restrictive in all aspects and should be considered exemplary. The scope of the embodiment should be determined by a reasonable interpretation of the appended claims, and all changes within the equivalent scope of the embodiment are included in the scope of the embodiment.

1. A magnet assembly device for a semiconductor light emitting device for pixels,
wherein the magnet assembly device is disposed on a predetermined assembly substrate and is to apply a magnetic force to the semiconductor light emitting device, comprising:
a magnet rotation part; and
a magnet unit mounted on the magnet rotation part,
wherein the magnet rotation part comprises a magnet driving part and a magnet gear part,
wherein the magnet unit is configured to rotate around a rotation axis including a N-pole magnet region and a S-pole magnet region, and
wherein the N-pole magnet region and the S-pole magnet region of the magnet unit are disposed in a direction parallel to a surface of the assembly substrate.

2. The magnet assembly device for the semiconductor light emitting device for pixels according to claim 1, wherein a center of the magnet unit is eccentrically disposed at a position deviating from a center of the magnet gear part.

3. The magnet assembly device for the semiconductor light emitting device for pixels according to claim 1, wherein the magnet unit is configured to rotate around a rotation axis (Rz) of the magnet driving part or an axis parallel thereto, and
wherein the rotation axis is disposed at an outer region of a boundary between the N-pole magnet region and the S-pole magnet region of the magnet unit.

4. The magnet assembly device for the semiconductor light emitting device for pixels according to claim 1, wherein the magnet unit further comprises a metal part including a ferromagnetic material on one or both sides of the N-pole magnet region or the S-pole magnet region (810S).

5. The magnet assembly device for the semiconductor light emitting device for pixels according to claim 1, wherein the magnet unit is configured to rotate around the rotation axis (Rz) of the magnet driving part or an axis parallel thereto, and
wherein the rotation axis is disposed at an outer part of the N-pole magnet region or an outer part of the S-pole magnet region.

6. A magnet assembly device for a semiconductor light emitting device for pixels,
wherein the magnet assembly device is disposed on a predetermined assembly substrate and is to apply a magnetic force to the semiconductor light emitting device, comprising:
a magnet rotation part; and
a magnet unit mounted on the magnet rotation part,
wherein the magnet rotation part comprises a magnet driving unit and a magnet gear unit, and
wherein a central axis of the magnet unit is rotated in a tilted state at a predetermined angle relative to a rotation axis of the magnet driving unit.

7. The magnet assembly device for the semiconductor light emitting device for pixels according to claim 6, wherein a first rotation radius of an upper side of the magnet unit is different from a second rotation radius of a lower side of the magnet unit.

8. The magnet assembly device for the semiconductor light emitting device for pixels according to claim 7, wherein the first rotation radius of the upper side of the magnet unit is less than the second rotation radius of the lower side of the magnet unit.

9. The magnet assembly device for the semiconductor light emitting device for pixels according to claim 6, wherein the N-pole magnet region and the S-pole magnet region of the magnet unit are disposed in a direction parallel to a surface of the assembly substrate.

10. The magnet assembly device for the semiconductor light emitting device for pixels according to claim 6, wherein the lower surface of the magnet unit is inclined with the surface of the assembly substrate.

11. The magnet assembly device for the semiconductor light emitting device for pixels according to claim 6, wherein a vertical cross-section of the magnet unit comprises a parallelogram shape.

12. The magnet assembly device for the semiconductor light emitting device for pixels according to claim 11, wherein the upper surface of the magnet unit is parallel to the surface of the magnet gear part.

13. The magnet assembly device for the semiconductor light emitting device for pixels according to claim 11, wherein the lower surface of the magnet unit is parallel to the surface of the assembly substrate.

14. The magnet assembly device for the semiconductor light emitting device for pixels according to claim 6, wherein a center of the magnet unit is eccentrically disposed at a position deviating from a center of the magnet gear part.

15. The magnet assembly device for the semiconductor light emitting device for pixels according to claim 6, wherein the magnet unit further comprises a metal part including a ferromagnetic material on one or both sides of the N-pole magnet region or the S-pole magnet region (810S).

16. A self-assembly apparatus for a display pixel semiconductor light emitting device comprising:
a chamber for accommodating a predetermined fluid and a plurality of semiconductor light emitting devices;
an assembly substrate disposed on the chamber; and
a magnet assembly device disposed on the assembly substrate,
wherein the magnet assembly device comprises the magnet assembly device for the pixel semiconductor light emitting device according to claim 1.
